(19) United States
(12) Patent Application Publication
(10) Pub. No.: US 2011/0268884 A1
(43) Pub. Date: Nov. 3, 2011

(54) FORMATION OF NANOSCALE CARBON NANOTUBE ELECTRODES USING A SELF-ALIGNED NANOGAP MASK

(75) Inventors: Samuel Jonas Wind, White Plains, NY (US); Jinyao Tang, New York, NY (US); James C. Hone, New York, NY (US); Yuyao Shan, New York, NY (US)

(73) Assignee: THE TRUSTEES OF COLUMBIA UNIVERSITY IN THE CITY OF NEW YORK, NEW YORK, NY (US)

(21) Appl. No.: 13/098,957

(22) Filed: May 2, 2011

Related U.S. Application Data
(60) Provisional application No. 61/330,741, filed on May 3, 2010.

(51) Int. Cl. B05D 3/14; B82Y 40/00

(52) U.S. Cl. 427/272; 118/620; 977/847

(57) ABSTRACT

A first single-wall carbon nanotube can be electrically coupled to a first electrode, and a second single-wall carbon nanotube electrically coupled to a second electrode. In an example, the first and second single-wall carbon nanotubes are laterally separated by a nanoscale gap, such as sized and shaped for insertion of a single molecule.

### CLAIM OF PRIORITY

This patent application claims the benefit of priority, under 35 U.S.C. Section 119(e), to Wind, et al., U.S. Provisional Patent Application Ser. No. 61/330,741, entitled “Formation of nanoscale carbon nanotube electrodes using a self-aligned nanogap mask,” filed on May 3, 2010 (Attorney Docket No. 2413.119PRV), which is hereby incorporated by reference herein in its entirety.

### STATEMENT REGARDING FEDERALLY SPONSORED RESEARCH OR DEVELOPMENT

This invention was made with government support under award number CHE-0641523 from the National Science Foundation (NSF). The government has certain rights in this invention.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to the drawings and photos that form a part of this document: Copyright 2010, The Trustees of Columbia University in the City of New York, All Rights Reserved.

### BACKGROUND

Carbon nanotubes are allotropes of carbon that can have a cylindrical structure. Such carbon nanotubes can be graphene cylinders, formed from a layer of graphite that can be one atom thick. Carbon nanotube cylinders can have a diameter of about 1 nanometer, and can be grown to lengths of several microns or more. Carbon nanotubes can have a single wall, such as to form a single cylindrical structure. Other nanotube structures can have multiple walls, such as to form several concentric cylinders.

Carbon nanotubes can have higher electrical and thermal conductivity than copper, and carbon nanotubes can also have higher resistance to electromigration than copper. In some examples, carbon nanotubes can be used as conductors or semiconductors, such as in the interconnect structures of semiconductor chips.

The present inventors have recognized, among other things, that a significant challenge to molecular electronic switches and sensors can be the fabrication of electrodes that are spaced apart by molecular dimensions. In some examples, gold electrodes spaced apart by molecular dimensions can be fabricated by electromigration. The size of these interelectrode gaps can be difficult to control, and can leave an uncontrolled number of bonding sites at the nanogap. Furthermore, gold may not form a stable bond with some useful organic molecules that would desirably be inserted into the gap. For example, where a thiolated molecule is to be inserted into the nanogap, there can be little control over the gold-thiol bond.

In some examples, carbon nanotubes can be used as electrodes in various electronic devices, such as transistors. Nanoscale gap regions can be formed between carbon nanotubes, such as can be bridged using functional elements at a molecular scale. An approach to producing nanoscale gaps includes using electron beam lithography, break junctions, electrochemical growth, or electromigration. Another approach, described by Matsui et al., in U.S. Patent Publication No. 2007/0200175, entitled “FUNCTIONAL DEVICE AND METHOD OF MANUFACTURING IT,” discloses applying an AC signal to nanotube electrodes to “burn off” a gap portion of a nanotube.

Self-aligned processes, including oxidation of a sacrificial etch layer, can be used to create interelectrode distances below 100 nm. For example, Fursina et al., in Applied Physics Letters 92, 2008, entitled “NANOGAPS WITH VERY LARGE ASPECT RATIOS FOR ELECTRICAL MEASUREMENTS,” refers to oxidation of a sacrificial Cr layer, patterning on top of the oxidized layer, and etching away the Cr/CrₓO_{y} layer to reveal nanogaps.

### OVERVIEW

The electrical properties of single-wall carbon nanotubes (SWNTs) can make them candidates for an active element (e.g., channel) of an electronic device such as a transistor. SWNTs can also be included as one or more of source or drain electrodes in a single-molecule device, such as a molecular transistor. SWNTs can be formed from pure carbon, which can form stable chemical bonds with other organic molecules. Carbon nanotubes are excellent conductors, with essentially one-dimensional points of contact with connecting molecules. Reaction sites can be well defined, and bonding between nanotube electrodes and organic molecules can be covalent. Such bonds can be good conductors via p-bonding networks.

The small size of a SWNT (e.g., on the order of a few nanometers) can reduce the phase space for bonding among nanoscale device elements. For example, devices with SWNTs can incorporate interconnections at a molecular level. Such a SWNT-molecule device can include a nanoscale gap or “nanogap” (e.g., less than about 10 nanometers) formed into one or more SWNTs, such as where a single molecule can be inserted. In one approach, SWNT-molecule device fabrication can include direct-write electron beam lithography. However, such an approach can be time consuming, and can suffer from low yield and poor repeatability as compared to other processes. Furthermore, electron beam lithography can be an energy and time intensive process, and resulting gap sizes can be difficult to control.

The present inventors have recognized, among other things, that a problem to be solved can include forming a nanoscale gap in a SWNT. In an example, the present subject matter can provide a solution to this problem, such as by using a self-aligned oxidation process.

In an example, a portion of a SWNT device can be fabricated by forming a gap in an SWNT, such as using a self-aligning oxide layer, formed on a thin metal film, as a mask. The present inventors have recognized, among other things, that a self-limiting oxidation of the thin metal film can be used to provide a molecular-scale nanogap suitable for the insertion of a molecule. For example, the nanogap can be formed by a self-aligning technique which includes placing a hard mask above the nanotube with a small gap that is created by self-limiting lateral oxidation of the thin metal film. The nanotube can then be etched (e.g., severed or cut), such as using an oxygen plasma, in areas not covered with the metal film mask. Thus, the tube can be etched only in the region under the nanogap in the metal. The metal film can then be stripped, allowing full access to the nanotube electrodes (e.g., providing a molecular-scale nanogap). Such electrodes can then be used in a variety of applications, including sensors (e.g., for molecular detection, or microscopy, such as scanning tunneling microscopy or atomic force microscopy, among others), or for use as electronic circuit elements such as one or more molecular-scale transistors. In an example, such fabrication techniques can be used to fabricate templates for nanoimprint lithography.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example of an array of single wall carbon nanotubes on a substrate.

FIG. 2 illustrates generally an example of transferring an array of carbon nanotubes to a top working surface of a semiconductor substrate.

FIG. 3 illustrates generally a second example of transferring an array of carbon nanotubes to a top working surface of a semiconductor substrate.

FIG. 4 illustrates generally an example of forming a nanoscale gap using an oxidation process.

FIG. 5 illustrates generally an example that can include segmenting a carbon nanotube.

FIGS. 6A, 6B, 6C, 6D, 6E, 6F, 6G, and 6H illustrate generally an example that can include applying a thin film, oxidizing a portion of the thin film, and segmenting a carbon nanotube.

FIGS. 7A, 7B, 7C, 7D, 7E, 7F, 7G, 7H, 7I, 7J, 7K, and 7L illustrate generally an example that can include applying a thin film, oxidizing a portion of the thin film, and segmenting a carbon nanotube.

FIG. 8 illustrates generally an example that can include depositing multiple sacrificial layers.

FIG. 9 illustrates generally an example that can include a photoresist undercut.

FIGS. 10A, 10B, 10C, 10D, and 10E illustrate generally an example that can include applying a photoresist and creating an undercut in the photoresist.

FIG. 11 illustrates generally an example that can include inserting a bridging molecule into a nanoscale gap region in a carbon nanotube.

FIG. 12 illustrates generally an example that can include a molecule inserted into a nanoscale gap region in a carbon nanotube.

### DETAILED DESCRIPTION

The present inventors have recognized, among other things, that single-wall carbon nanotubes (SWNT) can serve as highly conductive electrodes. Fabrication of SWNT-molecule junctions can be formed using a self-aligning process, such as including one more lithographic and oxidation techniques. In an example, an array (e.g., about 100 or more) of SWNT-molecule junction devices can be fabricated.

In an example, arrays of SWNTs can be grown, such as on an s-cut quartz substrate, including using a thin-evaporated Co film. In an example, the temperature, feedstock flow rate, and thickness of the Co film can be controlled, such as to fabricate a dense array of well-aligned SWNTs of a suitable length (e.g., an average SWNT length of about 200 μm). In an example, the nanotubes can be transferred to a device chip (e.g., another semiconductor substrate, a glass substrate, or one or more other surfaces), such as using a tape transfer, or a PMMA transfer process, among others. For example, an array of SWNTs can be transferred from a quartz substrate to a Si₃N₄ substrate.

In an example, the SWNTs can then be electrically coupled to metal lead wires. After coupling to one or more leadwires, a nanoscale gap can be created in one or more SWNTs, such as using a self-aligning fabrication process. For example, the size of the gap can be determined at least in part by a self-limiting lateral oxidation of an ultrathin metal layer, such as an Al layer deposited on top of the one or more SWNTs (e.g., the SWNT array transferred to the Si₃N₄ substrate). Such a technique can create hundreds of such gaps (e.g., gaps of less than about 10 nanometers), with a high degree of uniformity. In an example, the ultrathin metal layer can serve as a hard mask, such as allowing reactive ion etching (e.g., “cutting”) of the underlying SWNTs. For example, after etching, the metal can be removed, and molecules can be introduced into the gaps. Thus, the present inventors have also recognized that such a self-aligning fabrication technique can be used for producing large-scale arrays of SWNT-molecule junction devices, unlike one or more other approaches (e.g., unlike a direct-write e-beam approach).

### Carbon Nanotube Arrays and Array Transfer Techniques

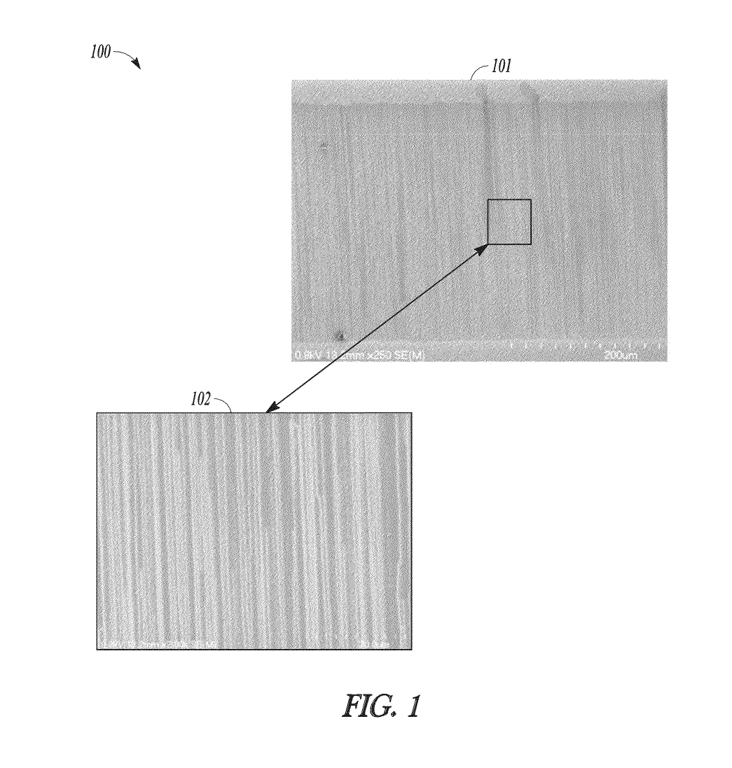

FIG. 1 illustrates generally a single-wall carbon nanotube (SWNT) array 100. In an example, SWNTs can be grown using a chemical vapor deposition (CVD) process. An example of suitable systems and methods describing SWNT growth via CVD are described, for example, in Jiang et al., U.S. Patent Publication No. 2009/0269257, entitled “APPARATUS FOR SYNTHESIZING A SINGLE-WALL CARBON NANOTUBE ARRAY,” which is hereby incorporated herein by reference. The method can include applying a catalyst, such as a thin metal film (e.g., cobalt (Co), nickel (Ni), etc.), to a substrate material, such as silicon, glass, or quartz, among others. The catalyst and substrate can be disposed in a heated CVD reaction chamber. Gaseous carbon, including single carbon atoms or clusters of plural carbon atoms, can be introduced to the chamber at a sufficient rate to support the high growth rate of SWNTs via a precision mass flow controller. A reactant gas, such as a hydrocarbon gas, can also be introduced. The reactant gas can undergo a catalytic reaction with the catalyst, and can decompose into carbon and hydrogen gas. In an example, the hydrogen gas can encourage SWNTs to form substantially along a direction that is vertical to the outer surface of the substrate. In an example, metal carbides can form in the reaction of the catalyst and the two gas sources, generating heat. To dissipate the heat, a densely aligned array of SWNTs can grow from the substrate material.

In the example of FIG. 1, a scanning electron microscope (SEM) image shows an example of densely packed SWNTs 101 formed using a CVD method. A zoomed in portion of the SWNT array is shown at 102 to illustrate the well-aligned SWNT array. Using the CVD method, many individual SWNTs can achieve a length of 200 μm or more.

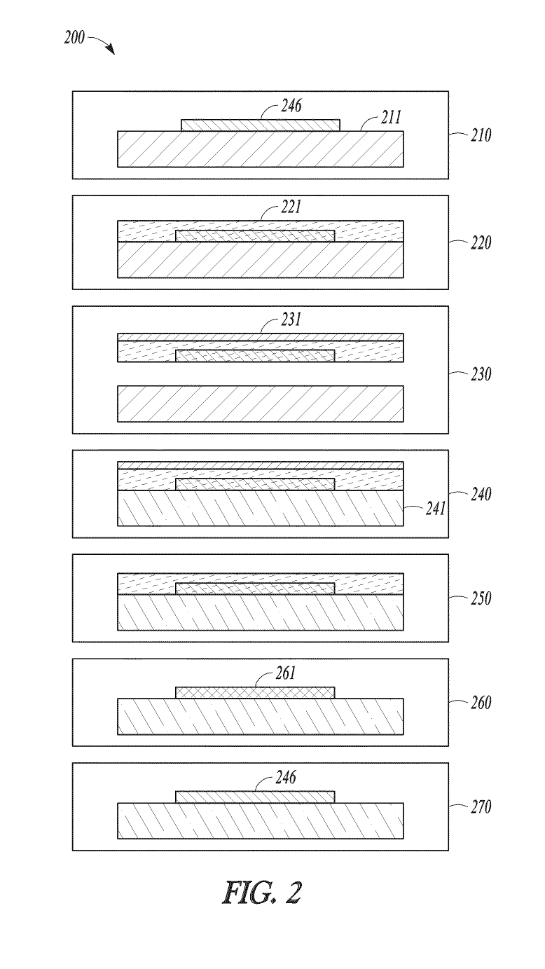

After a SWNT array is formed on a first substrate, the array can be transferred to a top working surface of a target substrate, such as by a tape transfer method or other method. FIG. 2 illustrates generally an example of a gold tape transfer method. For example, at 210, a SWNT 246 can be grown on a first substrate 211. In an example, the SWNT 246 can be an array of SWNTs. At 220, gold 221 can be applied to the top working surface of the first substrate 211, such as using an evaporation process, such as to at least partially cover the SWNT 246. At 230, water-soluble tape 231 can be applied to the top working surface (e.g., such as including the gold 221). The water-soluble tape 231 can be used to peel the SWNT 246 away from the first substrate 211. At 240, the SWNT 246, gold 221, and water-soluble tape 231 can be applied to a target substrate 241. At 250, the water-soluble tape 231 can be dissolved, such as using deionized water. At 260, a gold etchant can be applied to the apparatus. Residual material 261, including portions of the gold 221 and the water-soluble tape 231 can, in some examples, remain attached to the SWNT 246 after application of the gold etchant. At 270, a cleaner can be applied to the SWNT 246 and target substrate 241 to attempt to remove any remaining organic residues. For example, a mixture of sulfuric acid and hydrogen peroxide (e.g., Piranha) can be used, among other solutions.

The gold tape example in FIG. 2 can have several advantages. For example, the water-soluble tape 231 can be strong, easy to manage, and the tape can be manipulated in very small pieces. However, gold doping of the SWNT 246 can occur. Furthermore, available cleaning solutions (e.g., Piranha) can be harsh, and may damage the SWNT 246. In some cases, residual materials can be difficult to completely remove.

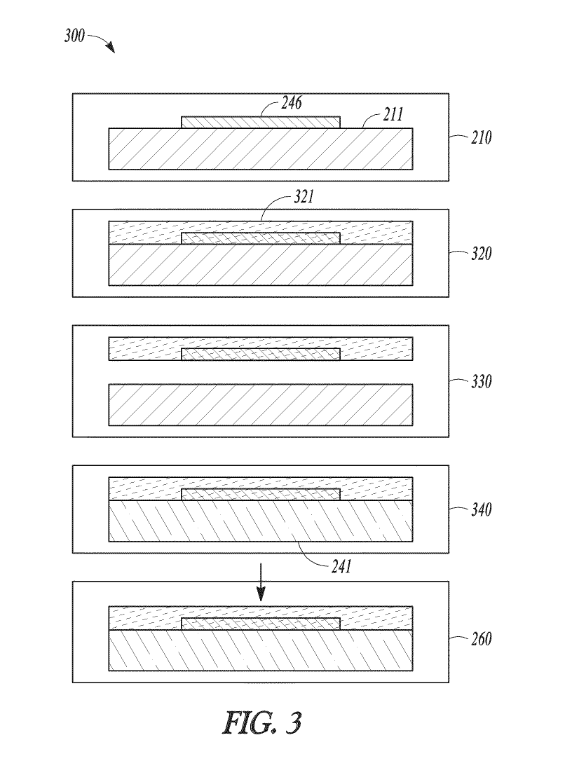

FIG. 3 illustrates generally an example of transferring a SWNT array to a top working surface of a target substrate. For example, at 210, a SWNT 246 can be grown on a first substrate 211. At 320, a photoresist (e.g., a positive photoresist such as poly(methyl methacrylate) (PMMA)) 321 can be used to coat the top surface of the first substrate 211, including the SWNT 246. At 330, a strong base material, such as potassium hydroxide (KOH), can be used to release the PMMA 321, including the SWNT 246, from the first substrate 211. The PMMA 321 and SWNT 246 can then be applied to the target chip 241, such as at 350. At 380, subsequent processes can be performed, such as electron-beam lithography. For example, subsequent processes can include cutting a SWNT 246, such as to form a specified gap in the SWNT 246.

The example of FIG. 3 can have several advantages over the gold 221 and water-soluble tape 231 based method illustrated in FIG. 2. For example, because PMMA 321 can be used as a portion of the transfer material, the nanotubes are not attacked or doped (such as by the hydrogen peroxide cleaner at 270, or by the deposition of gold 221 at 220). In contrast to gold 221, PMMA 321 can be easy to clean or remove from substrate surfaces. Furthermore, the contact between PMMA 321 and the SWNT 246 can be more robust than between gold 221 and a SWNT 246. In some examples, PMMA 321 can be used as a resist layer for subsequent electron-beam lithography. Although PMMA 321 is low in cost and can provide several advantages over the gold and tape process, some potential limitations to using PMMA 321 may exist. For example, PMMA 321 is a relatively soft material, and can be easily damaged (e.g., cracked, broken). In addition, PMMA 321 can be difficult to manipulate at the microscale.

### Nanogap Formation

In an example, planar metal electrodes separated by a very small distance, such as a few nanometer wide nanogap, can be fabricated. Several techniques can be used to create nanogaps, including electromigration, electrodeposition, mechanically controlled break junctions (MCB), e-beam lithography, and on-wire lithography, among other techniques. A successfully fabricated nanogap will not pass electrical current between the electrodes (e.g., measured currents would be below the measurable picoampere range), indicating an interelectrode resistance of at least tens of gigaohms. To achieve such high resistance, gap irregularities can be reduced or minimized such that no portion of the electrodes is near enough to permit tunneling (e.g., the gap length should be greater than about 1 to 2 nm).

In an example, a nanogap can be fabricated using at least two lithographic patterning steps to define first and second electrodes. The interelectrode spacing can be controlled by a self-aligned process including an oxidation of a thin metal sacrificial layer deposited on one of the electrodes. An example of a suitable self-aligned fabrication technique is presented in Tang et al., J. Vac. Sci. Technol. B 24(6), p. 3227 (2006), entitled “CHEMICALLY RESPONSIVE MOLECULAR TRANSISTORS FABRICATED BY SELF-ALIGNED LITHOGRAPHY AND CHEMICAL SELF-ASSEMBLY,” which is hereby incorporated herein by reference. Tang discusses a fabrication technique in which gross alignment (e.g., microscale) of two lithographic patterning steps is sufficient to achieve nanoscale precision because the nanogap is formed using a self-aligned process.

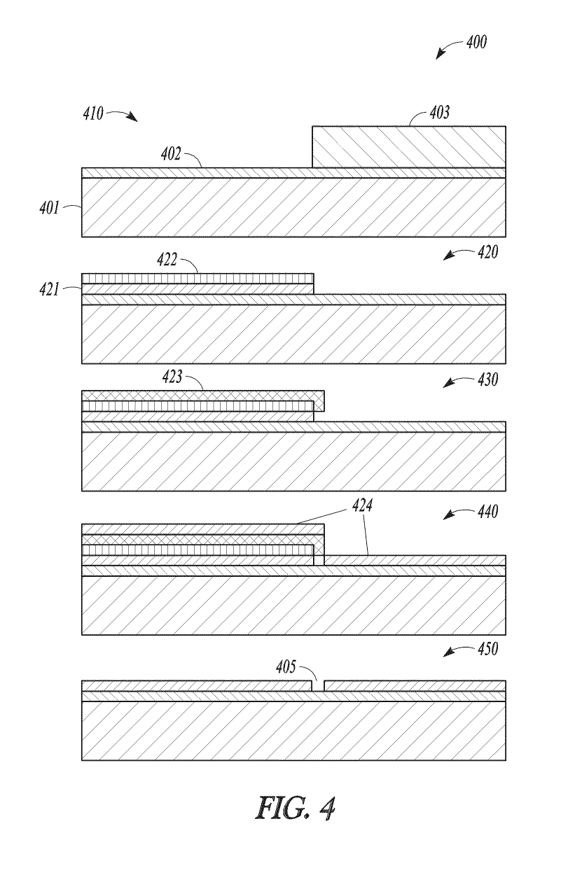

FIG. 4 illustrates generally an example of a nanogap that can be formed using two lithographic steps. For example, a first platinum (Pt) electrode 421 can be patterned using a first lithographic step on a first substrate 401. In an example, the first substrate 401 can be n-type silicon upon which a thin layer of ZrO₂ can be deposited to serve as a gating dielectric 402. The first Pt electrode 421 can be covered using a sacrificial (e.g., silicon dioxide (SiO₂)) layer, and a thin metal layer, such as an aluminum (Al) layer 422. The aluminum layer 422 can be oxidized (e.g., in ambient conditions), forming an oxidized portion of the Al layer 423. A second Pt electrode 424 can be deposited using a second lithographic step. The Al₂O₃, Al, and SiO₂ layers, and a portion of the second Pt electrode 424, can then be stripped, such as by immersion in an etchant solution (e.g., tetramethylammoniumhydroxide). In an example, the first Pt electrode 421 and a portion of the second Pt electrode 424 can be separated by a gap 405 proportional to the lateral thickness of Al₂O₃ layer (e.g., a nanoscale gap).

### Carbon Nanotube Nanogap Formation

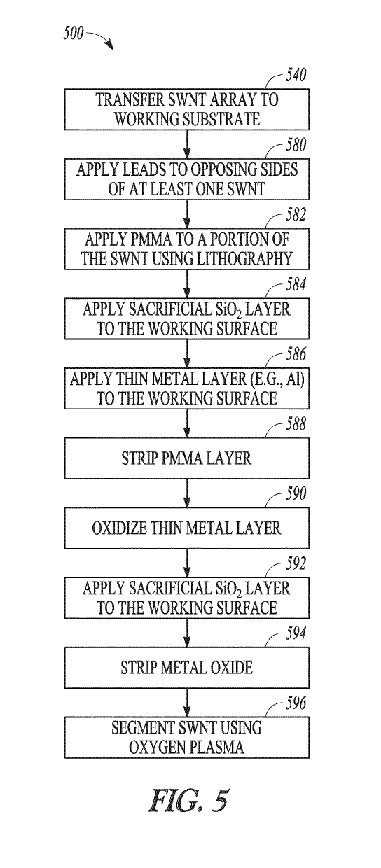

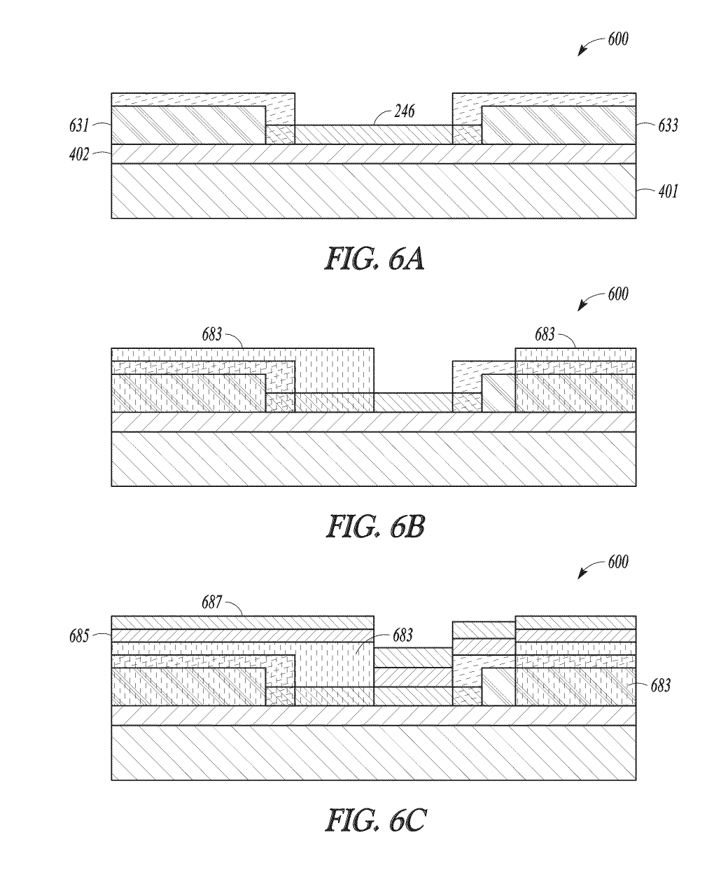

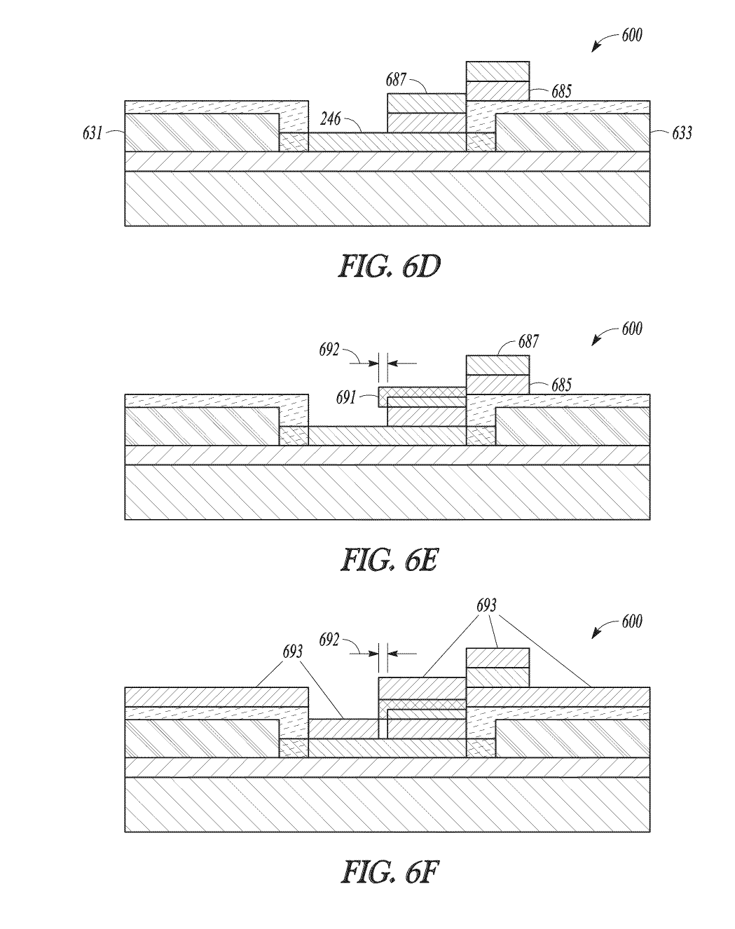

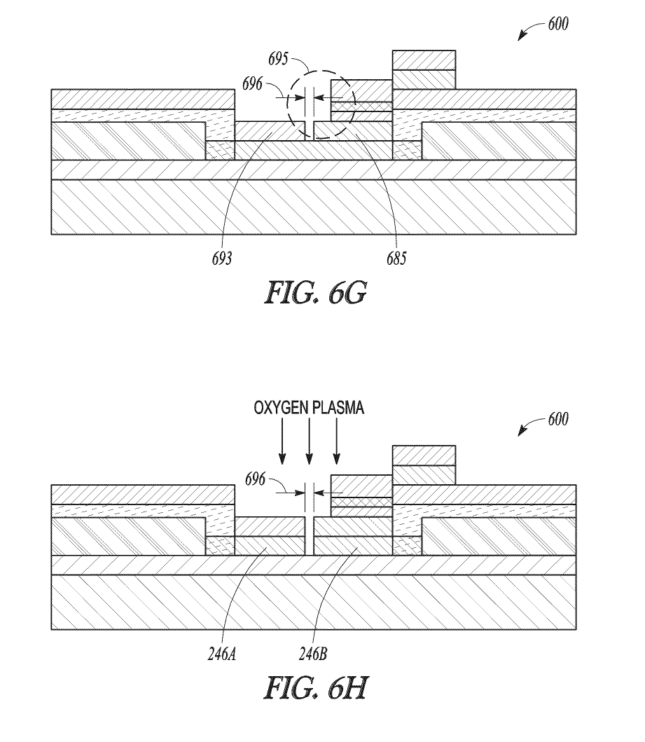

FIG. 5 and FIGS. 6A, 6B, 6C, 6D, 6E, 6F, 6G, and 6H illustrate generally examples that can include segmenting a carbon nanotube into two or more pieces. At 540, an array of single-wall carbon nanotubes can be transferred to a working surface of a substrate, such as a silicon wafer. The SWNT array can be transferred using PMMA, such as described above with respect to FIG. 3, or using gold tape, such as described above with respect to FIG. 2, or using another transfer technique.

At 580, electrode leads can be applied to opposing ends of at least one SWNT, such as one SWNT in the array of SWNTs transferred at 540. In an example, the electrode leads can be deposited by evaporation, such as using electron beam evaporation in a vacuum. In an example, chemical vapor deposition (CVD) can be used to form the electrode leads, such as where high aspect ratio feature coverage is desired. In an example, metal CVD or atomic layer deposition (ALD) can be used. FIG. 6A illustrates generally an example of electrode leads applied to a SWNT on a silicon wafer substrate. The example of FIG. 6A can include a first source electrode 631 and a second source electrode 633, wherein the first and second source electrodes can be deposited at opposing ends of a SWNT 246.

At 582, a photoresist (e.g., PMMA) can be applied to a portion of a working surface containing a SWNT (e.g., the SWNT 246) using lithography to form a selective masking layer. FIG. 6B illustrates generally an example in which PMMA 683 cam be deposited about the first source electrode 631, a portion of the SWNT 246, and a portion of the second source electrode 633. In an example, a portion of the SWNT 246 and a portion of the second source electrode 633 can be unmasked by the PMMA 683.

At 584, a sacrificial layer, such as a sacrificial SiO₂ layer, can be applied to the working surface, such as using CVD. In an example, chromium or another material can be applied at 584, such as instead of or in addition to SiO₂. Afterwards, a sacrificial layer, such as a sacrificial thin metal layer, can be applied to the working surface, such as using CVD, at 586. In an example, the sacrificial thin metal layer can include aluminum, copper, or nickel, among other materials. FIG. 6C illustrates generally an example that can include the SWNT 246, a selective masking layer of PMMA 683, a first sacrificial SiO₂ layer 685, and a sacrificial thin metal layer 687.

At 588, the PMMA layer (e.g., PMMA 683) can be stripped from the working surface, such as using an N-methylpyrrolidinone (NMP) based stripping material. FIG. 6D illustrates generally an example that can include the working surface stripped of the PMMA 683. For example, the first sacrificial SiO₂ layer 685 and the sacrificial thin metal layer 687 can remain on the working surface, including covering a portion of the SWNT 246 and a portion of the second source electrode 633, such as after the PMMA 683 is removed.

In the example of FIG. 5, a thin metal layer can be oxidized at 590. For example, the thin metal layer can include the sacrificial thin metal layer 687. FIG. 6E illustrates generally an example that can include an oxidized portion 691 of the sacrificial thin metal layer 687. In the example of FIG. 6E, the oxidized portion 691 can form, at least in part, in a lateral direction from the sacrificial thin metal layer 687. The oxidized portion 691 can include a lateral overhang 692 that can extend beyond an edge of the sacrificial SiO₂ layer. In an example, the length of the lateral overhang 692 of the oxidized portion 691 can be about 1 nm to 10 nm.

In an example, the magnitude (e.g., the length or size) of the lateral overhang 692 can be determined by a self-limiting oxidation process. The oxidized portion can include the native oxide that can grow by exposing the sacrificial thin metal layer 687 to air, such as at room temperature. The thickness of the oxidized layer can be just a few nanometers. In an example in which the sacrificial thin metal layer 687 includes aluminum, such as 2-5 nm thick, the lateral overhang 692 can be about 5 nm. The oxidation can be self-limited by one or more properties of the sacrificial thin metal layer 687, or by one or more environmental factors. In an example, a thicker sacrificial layer can yield a thicker layer of oxidation. Also, the oxidation process can be affected by oxygen partial pressure. For example, if the sacrificial thin metal layer 687 is oxidized at a low oxygen concentration, a thinner and denser oxide layer can form on the surface. In an example, this thin, dense layer can inhibit or prevent further oxidation, and can result in a very small lateral overhang 692. In an example, temperature and humidity can affect the self-limiting oxidation process. For example, an elevated temperature or humidity can enhance oxidation, which can create a larger or longer lateral overhang 692. In an example, the sacrificial thin metal layer 687 can be oxidized at least in part inside of an electron beam evaporator device.

At 592, a second sacrificial SiO₂ layer can be applied to the working surface, such as using electron beam evaporation. FIG. 6F illustrates generally an example of the second sacrificial SiO₂ layer 693 applied to the working surface of the device. The second sacrificial SiO₂ layer 693 can cover the lateral overhang 692 of the oxidized portion 691 of the sacrificial thin metal layer 687. In the example of FIG. 6F, the second sacrificial SiO₂ layer 693 does not contact at least a portion of the SWNT 246 (e.g., the portion of the SWNT 246 below the lateral overhang 692).

At 594, the metal oxide can be stripped, such as using a lift-off step. For example, the oxidized portion 691 of the sacrificial thin metal layer 687 can be removed from the working surface of the device. In an example, any material that is attached to the oxidized portion 691 can also be removed at 594. For example, the sacrificial thin metal layer 687, the oxidized portion 691, and at least a portion of the sacrificial SiO2 layer on the oxidized portion 691 can be removed, such as by immersion in an etchant solution. In an example, the sacrificial layers can be removed using an aqueous solution of tetramethylammoniumhydroxide. FIG. 6G illustrates generally the device 600 after a portion of the metal oxide is stripped. The portion 695, including portions of the sacrificial thin metal layer 687, the oxidized portion 691, and at least a portion of the sacrificial SiO2 layer on the oxidized portion 691, were removed from the device 600. After removing the portion 695, a gap 696 can exist between the first sacrificial SiO₂ layer 685 and the second sacrificial SiO₂ layer 693. In an example, the gap 696 can be just a few nanometers wide, such as a width between 1 nm and 10 nm, inclusive. In an example, the width of the gap 696 can be proportional to or approximately equal to the portion of the lateral overhang 692 extending over the SWNT 246.

At 596, a SWNT can be segmented, such as using oxygen plasma. FIG. 6H illustrates generally an example including applying oxygen plasma to the device 600 in the region of the gap 696. In an example, the plasma etch can be achieved at 250 mTorr, 50 Watts RF power, and 10 seconds exposure time. In an example, the SWNT 246 can be segmented electrochemically.

In an example, the SWNT 246 can be segmented, such as below the gap 696, into a first SWNT segment 246a and a second SWNT segment 246b. In an example, the first SWNT segment 246a can be spaced apart from the second SWNT segment 246b by a few nanometers, such as 5 nm.

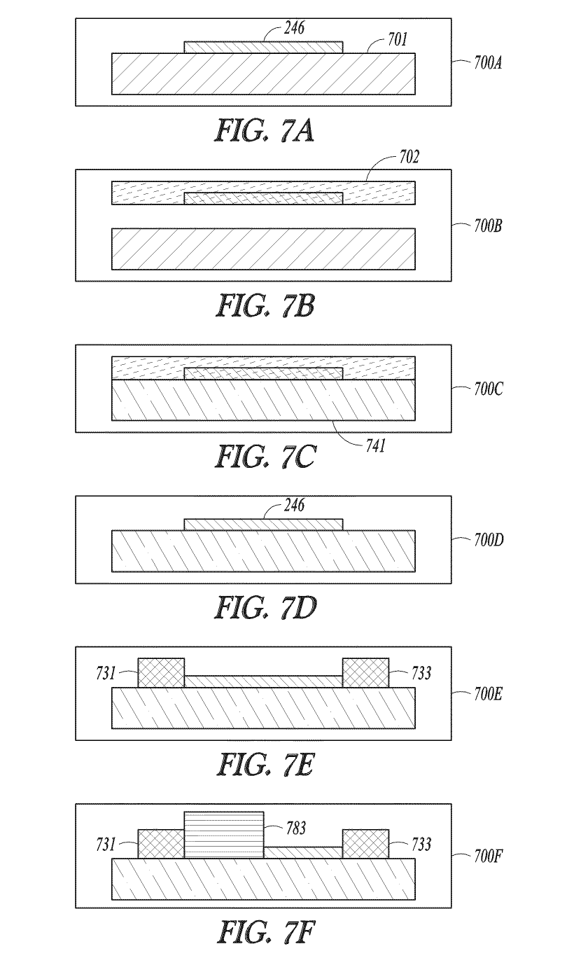

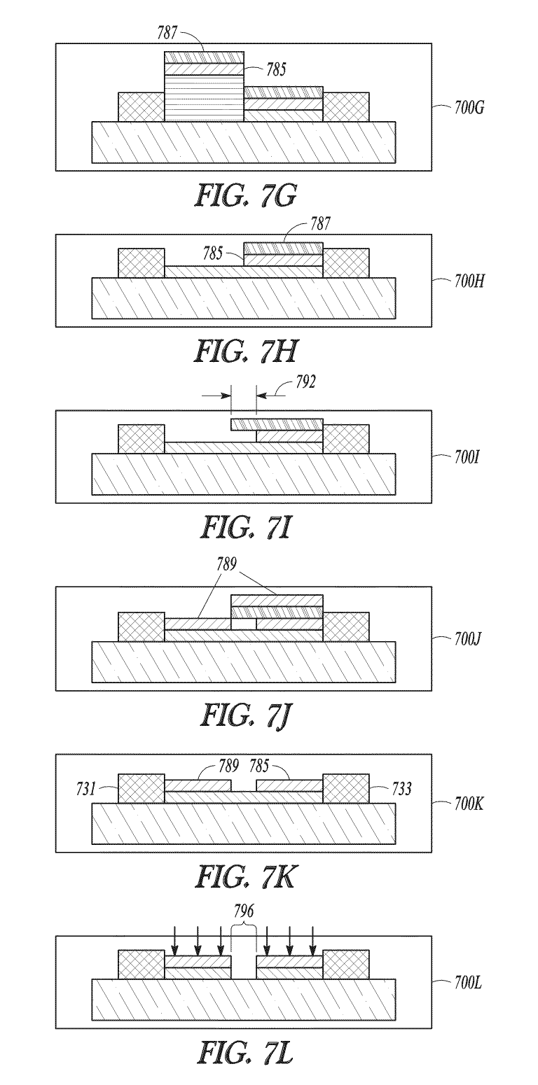

FIGS. 7A, 7B, 7C, 7D, 7E, 7F, 7G, 7H, 7I, 7J, 7K, and 7L illustrate generally an example that can include segmenting a carbon nanotube on a device. FIG. 7A, for example, illustrates growth of a SWNT 246, such as on a quartz chip 701. FIG. 7B illustrates generally a PMMA coating 702 applied to the SWNT 246, and peeling off the SWNT 246 and PMMA coating 702, such as using KOH.

FIG. 7C illustrates generally an example of the SWNT 246 and PMMA coating 702 that can be applied to a target chip 741 (e.g., a silicon substrate). FIG. 7D illustrates generally an example that can include the target chip 741 and the SWNT 246, such as after removing the PMMA coating 702 from FIG. 7C. In an example, the target chip 741 can include a silicon wafer, and the SWNT 246 can be disposed on the wafer. FIG. 7E illustrates generally an example that can include the target chip 741, the SWNT 246, and leads 731, 733 (e.g., thin metal leads), such as can be applied to opposing ends of a portion of the SWNT 246. In an example, nanotubes on the target chip 741 that are not electrically coupled to the leads 731, 733 can be removed, such as by selective etching. In an example, a photoresist or electron beam resist can be applied to mask areas of interest (e.g., areas including the SWNT 246 coupled to the leads 731, 733). Any nanotubes not shielded by the mask can be exposed to a blanket oxygen plasma, such as until they are completely removed from the top surface of the device.

FIG. 7F illustrates generally an example that can include a lithographic step, wherein PMMA 783 can be applied to at least a portion of the top working surface of the device 700F. For example, PMMA 783 can be disposed on at least a portion of the SWNT 246 and on at least a portion of one of the leads (e.g., the lead 731).

FIG. 7G illustrates generally an example that can include a device 700G such as after a deposition of one or more materials by evaporation. For example, a first evaporation layer 785, such as including SiO₂, can be deposited, such as on a portion of the device 700G (e.g., a portion including the PMMA 783, an exposed portion of the SWNT 246, and a portion of the lead 733). A subsequent, second evaporation layer 787, such as including Al, can be deposited, such as on the first evaporation layer 785. FIG. 7H illustrates generally an example of a device 700H such as after a liftoff procedure. In an example, the liftoff procedure can be performed such that the PMMA 783 (e.g., the PMMA 783 from FIGS. 7F and 7G) is removed from the device 700G. Any material deposited on top of the PMMA 783 (e.g., portions of the first and second evaporation layers 785 and 787) can also be removed from the device 700H.

FIG. 7I illustrates generally an example of a device 700I that can include an oxidized portion 792 of the second evaporation layer 787 (e.g., an aluminum layer). In an example, the oxidized portion 792 can form at least partially in a lateral direction, such as extending over the first evaporation layer 785 and the underlying SWNT 246. In an example, the oxidation can be a self-limiting process, such as limited by the quantity and purity of the underlying base material (e.g., aluminum), and various environmental factors, such as including temperature or pressure, among others.

FIG. 7J illustrates generally an example of a device 700J that can include a third evaporation layer 789. The third evaporation layer 789 can include a layer of SiO₂, such as a few nanometers thick. In an example, the third evaporation layer 789 can be evaporated on to a top layer of the device 700J, such as on to the oxidized portion 792 or an exposed portion of the SWNT 246. In an example, a portion of the SWNT 246, such as beneath the oxidized portion 792, can be shielded from exposure to the third evaporation layer 789.

FIG. 7K illustrates generally an example of a device 700K that can include the target chip 741, the leads 731 and 733, the SWNT 246, a portion of the first evaporation layer 785, and a portion of the third evaporation layer 789. In an example, the device 700J of FIG. 7J can be immersed in an etchant configured to etch the base material of the second evaporation layer 787, such as to yield the device 700K.

FIG. 7L illustrates generally an example of a device 700L, such as can be formed using the device 700K and a plasma or other etching process, such as an oxygen plasma. For example, after exposure to the oxygen plasma, the SWNT 246 can include a nanoscale gap 796. The nanoscale gap 796 can be located in a region of the SWNT 246 that is not covered by at least one of the first evaporation layer 785 or the third evaporation layer 789. In an example, the nanoscale gap 796 can be less than about 10 nm, and can be suitably sized and shaped for insertion of a single molecule, such as a diamine molecule. The width of the nanoscale gap 796 can be approximately equal to the width of the oxidized portion 792 extending over the SWNT 246. In an example, the device 700L can be formed using another etching technique, such as electron beam lithography.

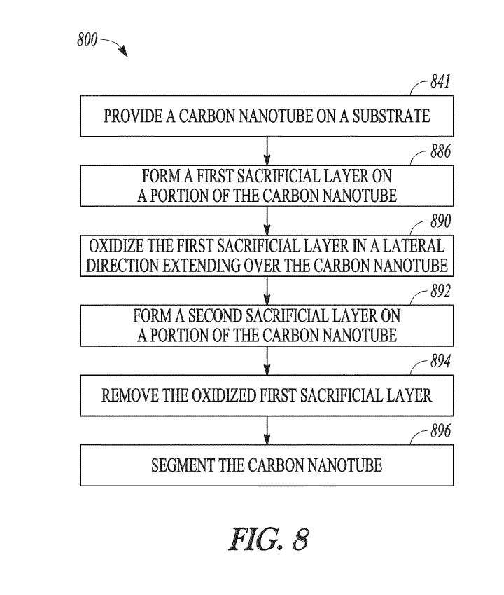

FIG. 8 illustrates generally an example 800 that can include segmenting a carbon nanotube, such as a single wall carbon nanotube or a multi-wall carbon nanotube. At 841, a carbon nanotube can be provided on a substrate. For example, the SWNT 246 can be provided on a Si wafer substrate, such as according to the discussion of FIG. 7D. In an example, the SWNT 246 can be provided on a substrate according to the discussion of FIGS. 2 and 3, which describe generally transferring an array of carbon nanotubes from a nanotube growth medium to a working surface of a target substrate (e.g., a Si wafer).

At 886, a first sacrificial layer can be formed on at least a portion of the carbon nanotube. For example, a sacrificial metal layer can be formed over a first longitudinal section of a single wall carbon nanotube (e.g., the SWNT 246), such as according to the discussion of FIG. 7H. In an example, the sacrificial metal layer can be formed over an intermediate sacrificial layer that is in contact with the carbon nanotube. At 890, the first sacrificial layer (i.e., the sacrificial metal layer) can be oxidized. The oxidation of the first sacrificial layer can be self-limited, such as described above with respect to FIG. 6E. For example, the amount of oxidation can be controlled by ambient conditions or by the thickness of the sacrificial layer formed at 886.

At 892, a second sacrificial layer can be formed on at least a portion of the carbon nanotube. In an example, the second sacrificial layer can cover the first sacrificial layer, including the oxidized portion of the first sacrificial layer. In an example, the second sacrificial layer can be prevented from contacting at least a portion of the carbon nanotube (e.g., the carbon nanotube provided at 841), such as a portion of the carbon nanotube beneath the oxidized portion of the first sacrificial layer.

At 894, the first sacrificial layer can be removed. In an example, the oxidized portion of the first sacrificial layer can also be removed. Once the first sacrificial layer and the oxidized portion of the first sacrificial layer are removed, at least a portion of the underlying carbon nanotube can be exposed. Other portions of the underlying carbon nanotube can be covered, such as by the second sacrificial layer or the intermediate sacrificial layer. At 896, the carbon nanotube can be segmented, such as by removing the exposed portion of the carbon nanotube. In an example, segmenting the carbon nanotube at 896 can be achieved according to the techniques described above at FIG. 6H or 7L, among other techniques.

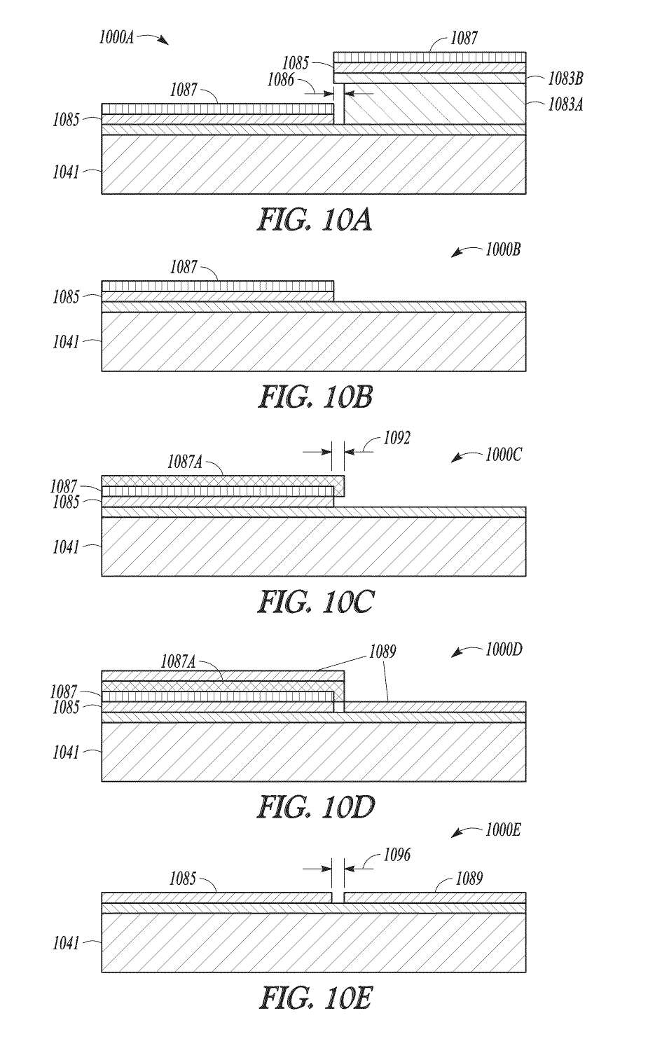

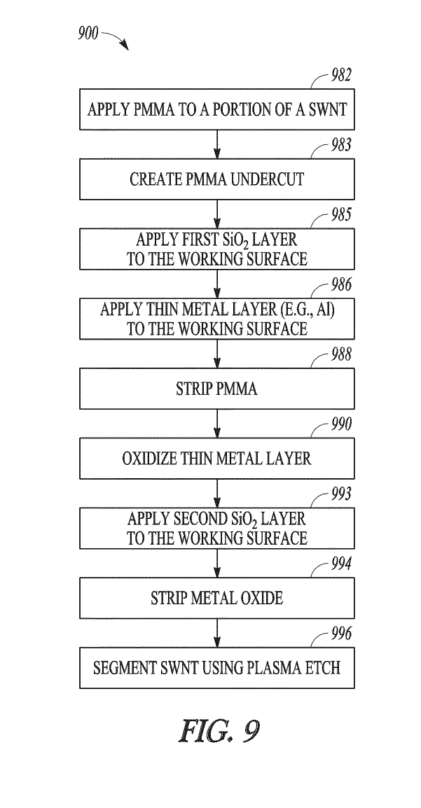

FIG. 9 and FIGS. 10A, 10B, 10C, 10D, and 10E illustrate generally examples that can include applying a photoresist (e.g., PMMA) to a top working surface of a semiconductor substrate, creating an undercut in the photoresist, and segmenting a carbon nanotube into two or more pieces. The example of FIGS. 9-10E can include improved edge geometries of evaporated materials. In an example, at 982, a first layer of PMMA can be applied to the working surface, such as including over a portion of a SWNT 246. A second photoresist layer (e.g., PMMA) can be applied. In an example, the double photoresist layer can be selectively spun onto a portion of the top working surface of the substrate, such as including the SWNT 246. At 983, a window with an undercut structure can be created in the first photoresist layer, such as after a lithographic electron beam writing. In an example, the first and second layers of photoresist can have different sensitivities to lithographic exposure (e.g., by having a lower molecular weight or a different chemical composition). In an example, the first (i.e., bottom) layer of photoresist can be more sensitive to the lithographic process, and can develop further in a lateral direction than the second (i.e., upper) layer of photoresist, such as given the same exposure. This can result in an undercut profile, such as illustrated in FIG. 10A. In an example in which a PMMA photoresist is used for the first and second layers, the second layer of PMMA can extend over the first layer of PMMA by the undercut amount.

At 985, a first layer of silicon dioxide can be applied to the top working surface of the device. In an example, the first layer of silicon dioxide can be applied on the second layer of PMMA and on a different, nearby, or adjacent portion of the top working surface of the semiconductor substrate, such as including the SWNT 246. In an example, the PMMA undercut structure can inhibit or prevent the first layer of silicon dioxide from reaching a portion of the top working surface, such as including a portion of the SWNT 246. At 986, a thin metal layer (e.g., aluminum) can be applied to the top working surface, such as can be in contact with the first layer of silicon dioxide applied at 985. In an example, the first layer of silicon dioxide and the thin metal layer can be evaporated onto the top working surface using an electron beam process. In an example, an edge of the silicon dioxide and thin metal layers can be approximately vertical (e.g., the edge nearest to the PMMA undercut structure).

In an example, the evaporation of a thin metal layer (e.g., aluminum), a layer of silicon dioxide, or a photoresist layer (e.g., PMMA), can introduce intrinsic stresses into the deposited materials. The stresses can include compression or tension stresses, and can bend the various layers toward or away from the underlying substrate. As the layers bend, the edges of these layers become thin and non-vertical. However, the bending is highly reproducible and predictable as a result of using the electron beam evaporation process. By carefully controlling the thickness of the layers and the dosage of the electron beam writing, any adverse effects of the intrinsic stresses can be reduced or eliminated. In addition, by using the PMMA undercut structure, the edges of the evaporated mask and thin metal (e.g., the silicon dioxide and aluminum layers) can better approximate ideal, vertical edge structures.

FIG. 10A illustrates generally a structure that can correspond to the example of FIG. 9, such as at 982, 983, 985, or 986. For example, the device 1000A can include a substrate 1041 (e.g., an n-type silicon substrate, such as n++Si). The first layer of PMMA 1083A can be applied to a portion of the top working surface of the substrate 1041, and the second layer of PMMA 1083B can be applied to the same or a different portion of the top working surface of the substrate 1041. In an example, the first and second layers of PMMA 1083A, 1083B at least partially overlap, and an e-beam writing technique can be used to create the undercut 1086. As illustrated in FIG. 10A, the second layer of PMMA 1083B can extend laterally over the first layer of PMMA 1083A, such as after the undercut creation using an e-beam.

The device 1000A can include a first layer of silicon dioxide 1085, such as can be deposited using evaporation. A thin metal layer 1087 can be deposited or otherwise formed over the first layer of silicon dioxide 1085, such as using one or more of an evaporative or sputtering technique, among others. The thin metal layer 1087 can include aluminum, copper, nickel, or one or more other materials, such as one or more other materials that can oxidize.

At 988, one or more PMMA layers (e.g., the first and second layers of PMMA 1083A, 1083B) can be stripped or otherwise removed from the working surface, such as using an N-methylpyrrolidinone (NMP) based stripping material, among others. FIG. 10B illustrates generally an example of a device 1000B that can include the device 1000A, such as after stripping the first and second layers of PMMA 1083A and 1083B. In an example, at least a portion of the first layer of silicon dioxide 1085 and at least a portion of the thin metal layer 1087 can remain on the working surface, such as covering a portion of the SWNT 246. In an example, a different portion of the first layer of silicon dioxide 1085 and a different portion of the thin metal layer 1087 (such as deposited or otherwise formed on the second layer of PMMA 1083B) can be removed from the working surface.

In the example of FIG. 9, the thin metal layer (e.g., the thin metal layer 1087) can be oxidized at 990. FIG. 10C illustrates generally an example of a device 1000C that can include a thin oxidized portion 1087A of the thin metal layer 1087. In the example of FIG. 10C, the thin oxidized portion 1087A can form, at least in part, in a lateral direction from the sacrificial thin metal layer 1087. The thin oxidized portion 1087A can include a lateral overhang 1092 that can extend past an edge of the first layer of silicon dioxide 1085. In an example, the length of the lateral overhang 1092 of the thin oxidized portion 1087A can be between about 1 nm to 10 nm, inclusive. In an example, the magnitude (e.g., the length or size) of the lateral overhang 1092 can be determined at least in part by a self-limiting oxidation process, as described above in the discussion of FIGS. 5 and 6A-6H.

At 993, a second layer of silicon dioxide 1089 can be applied to or formed upon the working surface (e.g., the working surface of the device 1000C, such as including the thin oxidized portion 1087A) such as using electron beam evaporation. FIG. 10D illustrates generally an example of a device 1000D that can include the second layer of silicon dioxide 1089 applied to the top working surface of the device 1000C. In an example, the second layer of silicon dioxide 1089 can be inhibited or prevented from contacting a portion of the top working surface of the substrate 1041, such as a portion of the substrate 1041 beneath the thin oxidized portion 1087A. In an example, the second layer of silicon dioxide 1089 can be inhibited or prevented from contacting at least a portion of a SWNT (e.g., the SWNT 246 disposed on the working surface of the substrate 1041) that can be disposed beneath the thin oxidized portion 1087A.

At 1094, the metal oxide (e.g., the thin oxidized portion 1087A) can be stripped or otherwise removed, such as using a lift-off step. In an example, the thin oxidized portion 1087A can be removed from the working surface of the device 1000D, such as to create the device 1000E as illustrated in FIG. 10E. In an example, any material that is attached to the thin oxidized portion 1087A can also be removed at 1094. In an example, at least a portion of the second layer of silicon dioxide 1089 can be removed, such as by immersion in an etchant solution.

FIG. 10E illustrates generally an example of a device 1000E, such as after the thin metal layer 1087 is removed from the top working surface of the substrate 1041. In an example, the first and second layers of silicon dioxide 1085 and 1089 can remain on the top working surface, such as separated by a nanoscale gap 1096 (e.g., about 1-10 nm wide). In an example, the width of the nanoscale gap 1096 can be proportional to or approximately equal to the length of the lateral overhang 1092.

At 1096, a SWNT can be segmented, such as according to the discussions of FIG. 5, 6H, or 7L, above. In an example, the SWNT 246 can be segmented, such as below the nanoscale gap 1096, into first and second SWNT segments that can be substantially axially aligned, and spaced apart by a few nanometers.

The examples in FIGS. 5-10 illustrate generally self-aligned techniques for creating nanometer-scale gaps on a top working surface of a substrate (e.g., the nanoscale gap 1096 created above the substrate 1041). Such substrates can include nanotubes, such as single-wall carbon nanotubes, that can be subsequently severed. The severed nanotubes can be configured to receive various molecular-scale organic compounds.

### Example of Adding Functional Elements to the Nanogap Region

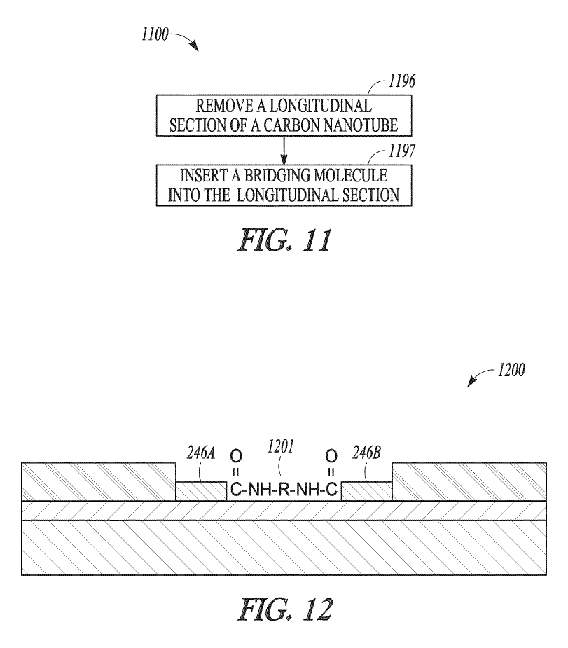

FIG. 11 illustrates generally an example 1100 that can include inserting a functional element into a nanoscale gap region formed in a carbon nanotube. In an example, at 1196, a longitudinal section of a carbon nanotube can be removed, such as to form a nanoscale gap region (e.g., less than about 10 nm wide). The longitudinal section of the carbon nanotube can be removed such as according to the discussion at FIGS. 5 and 8. At 1197, a single molecule can be inserted into the nanoscale gap region, such as to bridge the gap between opposing segments of the carbon nanotube. In an example, a single molecule can be inserted into a vacant longitudinal section of a segmented carbon nanotube (e.g., the SWNT 246). In an example, the single molecule can be covalently bonded with or otherwise attached to opposing ends of the carbon nanotube nanoscale gap region.

In an example, multiple molecules or longer chain molecules can be inserted into or attached within the nanoscale gap region at 1197. For example, cruciform π-systems can be used, such as having a terphenyl arm crossed with a conjugated bisoxazole arm. Such molecules can be functionalized using one or more endgroup molecules, such as can enable further attachment to one or more other organic molecules. In an example, the molecules inserted into the nanoscale gap region at 1197 can be inserted in or can form an ordered monolayer. In an example, a molecule can be introduced to the carbon nanotube nanoscale gap region (e.g., the nanoscale gap 796) such as by soaking a device (e.g., the device 700L) in a solution including functionalized molecules configured to assemble on or attach to an exposed portion of a carbon nanotube.

FIG. 12 illustrates generally an example of a device 1200 that can include a segmented carbon nanotube and a molecule inserted into or attached within a carbon nanotube gap region. The inserted molecule 1201 can be, for example, a diamine molecule, which can be covalently bonded to a first SWNT segment 246A and further covalently bonded to a second SWNT segment 246B. In an example, the first and second SWNT segments 246A and 246B can be substantially axially aligned. In an example, the inserted molecule 1201 can include any functional or organic molecule. In the example of FIG. 12, the inserted molecule 1201 can include a carbonyl group (C=0) linked to a nitrogen atom (N) (i.e., an amide, a functional group including a carbonyl group linked to a nitrogen atom). The amide can be linked to an R group. In an example, the inserted molecule 1201 can be configured to electrically couple the first and second SWNT segments 246A and 246B.

In an example, other molecules can be inserted into the nanoscale gap region. The molecules can be functionalized, such as with appropriate end groups, which can be selectively attached to an end of a carbon nanotube that terminates at the nanoscale gap region (e.g., at one of the opposing faces of the segments of the first and second SWNT segments 246A and 246B, as illustrated in FIG. 12). In an example, another end of the functional molecule can be left to be recognized by molecules or ions from a solution or other electrode. In an example, the device 1200 can be designed with particular chemical or electrical functionality. In an example, the length of the inserted molecule can be modified by the assembly.

### Additional Notes & Examples

Example 1 can include subject matter such as a method, a means for performing acts, or a machine-readable medium including instructions that, when performed by the machine, cause the machine to perform acts, comprising forming a sacrificial layer on a portion of a carbon nanotube, oxidizing a portion of the sacrificial layer in a lateral direction extending over the carbon nanotube, forming a masking layer on a working surface of the sacrificial layer and on the carbon nanotube, such that the oxidized portion of the sacrificial layer inhibits the masking layer from contacting a portion of the carbon nanotube, removing the oxidized portion after forming the masking layer, or removing a portion of the carbon nanotube to form a nanoscale gap below the removed oxidized portion of the sacrificial layer.

In Example 2, the subject matter of Example 1 can optionally include forming a sacrificial metal layer (e.g., a thin aluminum layer) on a portion of a single-wall carbon nanotube.

In Example 3, the subject matter of one or any combination of Examples 1-2 can optionally include removing a longitudinal section of a carbon nanotube that is less than about 10 nanometers wide.

In Example 4, the subject matter of one or any combination of Examples 1-3 can optionally include oxidizing a portion of a sacrificial layer using a self-limited oxidation of a thin film (e.g., a self-limited oxidation of a thin aluminum film).

In Example 5, the subject matter of one or any combination of Examples 1-4 can optionally include introducing a bridging molecule with a metal-ion core in the nanoscale gap. In an example, the bridging molecule can include a diamine.

In Example 6, the subject matter of one or any combination of Examples 1-7 can optionally include attaching first and second electrodes to opposing ends of a carbon nanotube, such that the carbon nanotube can function as a conductor between the first and second electrodes.

In Example 7, the subject matter of one or any combination of Examples 1-6 can optionally include forming a masking layer on a working surface of a sacrificial layer and on a carbon nanotube. In an example, the masking layer can be formed using one or more of aluminum, platinum, or chromium.

In Example 8, the subject matter of one or any combination of Examples 1-7 can optionally include removing a portion of a carbon nanotube to form a nanoscale gap, including laterally segmenting the carbon nanotube into a first carbon nanotube and a second carbon nanotube, separated by the nanoscale gap, using reactive ion etching. In an example, the first and second carbon nanotubes are axially aligned.

In Example 9, the subject matter of one or any combination of Examples 1-8 can optionally include removing a portion of a carbon nanotube to form a nanoscale gap, including laterally segmenting the carbon nanotube into a first carbon nanotube and a second carbon nanotube, separated by a nanoscale gap. In an example, the laterally segmenting the carbon nanotube can be achieved using an oxygen plasma.

In Example 10, the subject matter of one or any combination of Examples 1-9 can optionally include forming a carbon nanotube from an evaporated cobalt film, such as on a quartz substrate. Example 10 can include transferring the carbon nanotube, such as using a PMMA medium, to a working surface of a different substrate, such as a silicon nitride substrate.

In Example 11, the subject matter of one or any combination of Examples 1-10 can optionally include forming a single-wall carbon nanotube on a first substrate, transferring the single-wall carbon nanotube to a working surface of a second substrate, attaching a first electrode to the working surface of the second substrate and to a first portion of the single-wall carbon nanotube, attaching a second electrode to the working surface of the second substrate and to a second portion of the single-wall carbon nanotube, the second portion of the single-wall carbon nanotube opposite the first portion of the single-wall carbon nanotube, forming a sacrificial metal layer on the working surface of the second substrate, oxidizing the sacrificial metal layer in a lateral direction, forming a masking layer on the working surface of the second substrate using the oxidized portion of the sacrificial metal layer as a mask to inhibit the masking layer from contacting a third portion of the carbon nanotube, removing the oxidized portion after the formation of the masking layer, or removing a portion of the single-wall carbon nanotube to form a nanoscale gap below the removed oxidized portion of the sacrificial metal layer and between the first and second electrodes.

In Example 12, the subject matter of one or any combination of Examples 1-11 can optionally include subject matter such as an apparatus, comprising a semiconductor substrate, a first electrode on the semiconductor substrate, a second electrode on the semiconductor substrate that is spaced apart from the first electrode, a first carbon nanotube coupled to the first electrode, or a second carbon nanotube coupled to the second electrode. Example 12 can include first and second carbon nanotubes that can be approximately coaxial and separated by a self-aligned nanoscale gap. Example 12 can include subject matter such as a semiconductor device.

In Example 13, the subject matter of one or any combination of Examples 1-12 can optionally include subject matter such as a first carbon nanotube and a second carbon nanotube that can be single-wall carbon nanotubes.

In Example 14, the subject matter of one or any combination of Examples 1-13 can optionally include subject matter such as a nanoscale gap that can be less than about 10 nanometers wide.

In Example 15, the subject matter of one or any combination of Examples 1-14 can optionally include subject matter such as at least one bridging molecule with a metal-ion core. In an example, the at least one bridging molecule can be disposed in a self-aligned nanoscale gap.

In Example 16, the subject matter of one or any combination of Examples 1-15 can optionally include subject matter such as a self-aligned nanoscale gap that can be formed by forming a sacrificial layer on a working surface of a semiconductor substrate, oxidizing a portion of the sacrificial layer in a lateral direction, forming a masking layer on the working surface of the semiconductor substrate using the oxidized portion of the sacrificial layer as a mask to inhibit the masking layer from contacting a portion of a carbon nanotube, removing the oxidized portion of the sacrificial layer, or removing a portion of the carbon nanotube to form the self-aligned nanoscale gap below the removed oxidized portion of the sacrificial layer, and between the first and second carbon nanotubes.

In Example 17, the subject matter of one or any combination of Examples 1-16 can optionally include subject matter such as a self-aligned nanoscale gap that can be formed by reactive ion etching, such as to laterally segment a carbon nanotube into a first carbon nanotube and a second carbon nanotube.

In Example 18, the subject matter of one or any combination of Examples 1-17 can optionally include subject matter such as a self-aligned nanoscale gap that can be formed using oxygen plasma to laterally segment the carbon nanotube into a first carbon nanotube segment and a second carbon nanotube segment.

In Example 19, the subject matter of one or any combination of Examples 1-18 can optionally include subject matter such as a self-aligned nanoscale gap that can be formed by oxidizing a portion of a sacrificial layer in a lateral direction, such as using a self-limited oxidation of a thin film.

In Example 20, the subject matter of one or any combination of Examples 1-19 can optionally include subject matter such as a thin film, including one or more of aluminum, platinum, or chromium.

In Example 21, the subject matter of one or any combination of Examples 1-20 can optionally include subject matter such as forming a sacrificial layer on a portion of a carbon nanotube, including forming a resist layer (e.g., a layer of PMMA) over a portion of a carbon nanotube, forming an undercut between a top portion of the resist and a top working surface of a substrate, such as including the carbon nanotube, wherein the forming an undercut can be accomplished using an electron beam. Example 21 can include forming a sacrificial metal layer over a portion of the carbon nanotube and at least a portion of the top portion of the resist, oxidizing the sacrificial metal layer in a lateral direction extending over at least a portion of the carbon nanotube, and applying a second sacrificial layer (e.g., silicon dioxide).

These non-limiting examples can be combined in any permutation or combination.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A method, comprising:
forming a sacrificial layer on a portion of a carbon nanotube;
oxidizing a portion of the sacrificial layer in a lateral direction extending over the carbon nanotube;
forming a masking layer on a working surface of the sacrificial layer and on the carbon nanotube, such that the oxidized portion of the sacrificial layer inhibits the masking layer from contacting a portion of the carbon nanotube;
removing the oxidized portion after forming the masking layer; and
removing a portion of the carbon nanotube to form a nanoscale gap below the removed oxidized portion of the sacrificial layer.

2. The method of claim 1, wherein the forming a sacrificial layer on a portion of a carbon nanotube includes forming a sacrificial metal layer on a portion of a single-wall carbon nanotube.

3. The method of claim 1, wherein the removing a portion of the carbon nanotube to form a nanoscale gap includes removing a longitudinal section of the carbon nanotube that is less than about 10 nanometers wide.

4. The method of claim 1, wherein the oxidizing a portion of the sacrificial layer includes oxidizing a portion of the sacrificial layer using a self-limited oxidation of a thin film.

5. The method of claim 1, including introducing a bridging molecule with a metal-ion core in the nanoscale gap.

6. The method of claim 1, comprising attaching first and second electrodes to opposing ends of the carbon nanotube.

7. The method of claim 1, wherein the forming a masking layer on a working surface of the sacrificial layer and on the carbon nanotube includes forming the masking layer using one or more of aluminum, platinum, or chromium.

8. The method of claim 1, wherein the removing a portion of the carbon nanotube to form a nanoscale gap comprises:
laterally segmenting the carbon nanotube into a first carbon nanotube and a second carbon nanotube, separated by the nanoscale gap, using reactive ion etching.

9. The method of claim 1, wherein the removing a portion of the carbon nanotube to form a nanoscale gap comprises:
laterally segmenting the carbon nanotube into a first carbon nanotube and a second carbon nanotube, separated by the nanoscale gap, using an oxygen plasma.

10. The method of claim 1, wherein the forming a sacrificial layer on a portion of a carbon nanotube includes:
forming a resist layer over a portion of a carbon nanotube;
forming an undercut between a top portion of the resist and the carbon nanotube; and
forming a sacrificial metal layer over a portion of the carbon nanotube and at least a portion of the top portion of the resist.

11. An apparatus, comprising:
a semiconductor substrate;
a first electrode on the semiconductor substrate;
a second electrode on the semiconductor substrate that is spaced apart from the first electrode;
a first carbon nanotube coupled to the first electrode; and
a second carbon nanotube coupled to the second electrode;
wherein the first and second carbon nanotubes are approximately coaxial and separated by a self-aligned nanoscale gap.

12. The apparatus of claim 11, wherein the first carbon nanotube and the second carbon nanotube are single-wall carbon nanotubes.

13. The apparatus of claim 11, wherein the nanoscale gap is less than about 10 nanometers wide.

14. The apparatus of claim 11, including at least one bridging molecule with a metal-ion core in the self-aligned nanoscale gap.

15. The apparatus of claim 11, wherein the self-aligned nanoscale gap is formed by:
forming a sacrificial layer on the working surface of the semiconductor substrate;
oxidizing a portion of the sacrificial layer in a lateral direction;
forming a masking layer on the working surface of the semiconductor substrate using the oxidized portion of the sacrificial layer as a mask to inhibit the masking layer from contacting a portion of a carbon nanotube;
removing the oxidized portion of the sacrificial layer; and
removing a portion of the carbon nanotube to form the self-aligned nanoscale gap below the removed oxidized portion of the sacrificial layer, and between the first and second carbon nanotubes.

16. The apparatus of claim 15, wherein the self-aligned nanoscale gap is formed by reactive ion etching to laterally segment the carbon nanotube into the first carbon nanotube and the second carbon nanotube.

17. The apparatus of claim 15, wherein the self-aligned nanoscale gap is formed using oxygen plasma to laterally segment the carbon nanotube into the first carbon nanotube and the second carbon nanotube.

18. The apparatus of claim 15, wherein the self-aligned nanoscale gap is formed by oxidizing a portion of the sacrificial layer in a lateral direction using a self-limited oxidation of a thin film.

19. The apparatus of claim 15, wherein the self-aligned nanoscale gap is formed by:
forming a sacrificial layer on a portion of a carbon nanotube;
forming a resist layer over a portion of a carbon nanotube; and
forming an undercut between a top portion of the resist and the carbon nanotube; and
forming a sacrificial metal layer over a portion of the carbon nanotube and at least a portion of the top portion of the resist.

20. A method, comprising:
forming a single-wall carbon nanotube on a first substrate;
transferring the single-wall carbon nanotube to a working surface of a second substrate;
attaching a first electrode to the working surface of the second substrate and to a first portion of the single-wall carbon nanotube;
attaching a second electrode to the working surface of the second substrate and to a second portion of the single-wall carbon nanotube, the second portion of the single-wall carbon nanotube opposite the first portion of the single-wall carbon nanotube;
forming a sacrificial metal layer on the working surface of the second substrate;
oxidizing the sacrificial metal layer in a lateral direction;
forming a masking layer on the working surface of the second substrate using the oxidized portion of the sacrificial metal layer as a mask to inhibit the masking layer from contacting a third portion of the carbon nanotube;
removing the oxidized portion after the formation of the masking layer; and
removing a portion of the single-wall carbon nanotube to form a nanoscale gap below the removed oxidized portion of the sacrificial metal layer and between the first and second electrodes.
